(19) United States
(12) Patent Application Publication
(10) Pub. No.: US 2026/0223330 A1
(43) Pub. Date: Jul. 30, 2026

(54) REVERSIBLE DYNAMIC CONTACT ANGLE COOLING ASSEMBLIES AND SYSTEMS

(71) Applicant: Toyota Motor Engineering & Manufacturing North America, Inc., Plano, TX (US)

(72) Inventor: Shailesh Joshi, Ann Arbor, MI (US)

(73) Assignee: Toyota Motor Engineering & Manufacturing North America, Inc., Plano, TX (US)

(21) Appl. No.: 19/037,854

(22) Filed: Jan. 27, 2025

(51) Int. Cl. H05K 7/20

(52) U.S. Cl. CPC H05K 7/20381; H05K 7/20318; H05K 7/20327; H05K 7/20336

(57) ABSTRACT

A cooling assembly for phase-change cooling and thermal management includes a housing including a bottom planar mechanism, a side wall, an upper wall positioned opposite of the bottom planar mechanism and spaced apart by the side wall to define a cavity, and one or more pillars arranged within the cavity, the pillars comprising a top end and a bottom end. The top end of the pillars comprises one or more thermosensitive hydrogels. The bottom end of the pillars is mechanically coupled to the bottom planar mechanism.

### TECHNICAL FIELD

The present specification generally relates to thermal regulation, and more particularly, to controlling wetting conditions of coolant for different thermal loads.

### BACKGROUND

Cooling systems often rely on surfaces with fixed wetting properties, which are optimized for a specific operating condition. However, operating conditions change dynamically, and a fixed wetting property may be suitable for one operating condition by not another. Consequently, there is a need for cooling systems to have adaptive and dynamic wetting properties for different thermal loads.

### SUMMARY

In one embodiment, a cooling assembly for phase-change cooling and thermal management includes a housing including a bottom planar mechanism, a side wall, an upper wall positioned opposite of the bottom planar mechanism and spaced apart by the side wall to define a cavity, and one or more pillars arranged within the cavity. The pillars include a top end and a bottom end. The top end of the pillars comprises one or more thermosensitive hydrogels. The bottom end of the pillars is mechanically coupled to the bottom planar mechanism.

In another embodiment, a cooling assembly for phase-change cooling and thermal management includes a housing comprising a bottom planar mechanism, a side wall, an upper wall positioned opposite of the bottom planar mechanism and spaced apart by the side wall to define a cavity, a condenser fluidly coupled to the cavity, and one or more pillars arranged within the cavity. The pillars include a top end and a bottom end. The top end of the pillars comprises one or more thermosensitive hydrogels. The bottom end of the pillars is mechanically coupled to the bottom planar mechanism.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1A schematically depicts a cross-sectional perspective view of an example reversible dynamic contact angle cooling system according to one or more embodiments shown and described herein;

FIG. 1B schematically depicts a cross-sectional perspective view of the example reversible dynamic contact angle cooling system having an external condenser according to one or more embodiments shown and described herein;

FIG. 1C schematically depicts a cross-sectional perspective view of the example reversible dynamic contact angle cooling system having a wick according to one or more embodiments shown and described herein;

FIG. 2A schematically depicts a partially isolated perspective view of the example reversible dynamic contact angle cooling system of FIGS. 1A and 1B at high heat flux according to one or more embodiments shown and described herein;

FIG. 2B schematically depicts a partially isolated perspective view of the example reversible dynamic contact angle cooling system of FIG. 2A at high heat flux according to one or more embodiments shown and described herein;

FIG. 3A schematically depicts a partially isolated perspective view of the example reversible dynamic contact angle cooling system at low heat flux according to one or more embodiments shown and described herein;

FIG. 3B schematically depicts a partially isolated top perspective view of the example reversible dynamic contact angle cooling system of FIG. 3A at low heat flux according to one or more embodiments shown and described herein; and

FIG. 4 schematically depicts a non-limiting coolant boiling curve in the reversible dynamic contact angle cooling system according to one or more embodiments shown and described herein.

### DETAILED DESCRIPTION

Existing cooling systems often rely on surfaces with fixed wetting properties, which are optimized for specific scenarios but fail to adapt dynamically to changing thermal loads. Static designs, such as sintered particle wicks or screen meshes in heat pipes and vapor chambers, are often incapable of adjusting liquid transport and evaporation characteristics based on varying heat flux. For example, hydrophilic surfaces are effective for high heat flux scenarios due to their ability to promote filmwise boiling, maximizing heat transfer through larger contact areas. However, they become inefficient at low heat fluxes as excessive liquid retention increases thermal resistance. Conversely, hydrophobic surfaces excel in low heat flux conditions by facilitating dropwise boiling, which promotes vapor removal, but perform poorly under high heat flux where insufficient liquid spreading can cause localized overheating.

Further, existing cooling systems also face issues of thermal resistance caused by liquid pooling or inadequate vapor removal. For example, at low heat flux, liquid may stagnate on hydrophilic surfaces, forming insulating layers that hinder heat transfer. Conversely, at high heat flux, hydrophobic surfaces may lead to excessive vapor accumulation, creating vapor blankets that reduce the efficiency of heat dissipation and lead to critical heat flux (CHF). These limitations are particularly problematic in applications with fluctuating or localized heat loads, such as high-performance electronics, where traditional systems struggle to maintain consistent cooling performance.

Embodiments of the present disclosure are directed to thermal regulation assemblies and systems including a housing with a cavity and a pillar array within the cavity. The disclosed assemblies and systems further include thermosensitive hydrogels on top of the pillar array. The thermosensitive hydrogels can dynamically adapt surface wetting conditions in response to varying heat flux. For example, at low heat flux, the hydrogels of the disclosed assemblies and systems can swell, forming a blocking layer with hydrophobic properties. This hydrophobic surface of the hydrogels allows the coolant to nucleate with a large wetting angle to support dropwise boiling and reduces the thermal resistance associated with liquid films, improving heat transfer efficiency under low or mild thermal loads. Moreover, the large contact angle lowers the onset of the nucleate boiling (ONB) point of the coolant, allowing for improved thermal management under these conditions. At high heat flux, the hydrogels shrink, exposing the underlying hydrophilic surface of the bottom planar mechanism. The hydrophilic surface of the bottom planar mechanism promotes the wetting of the coolant thoroughly and encourages filmwise boiling, which is advantageous at higher heat flux by enabling efficient bubble detachment. The hydrophilic surface ensures rapid spreading of the coolant and consistent liquid supply to the hot regions, preventing the dry-out of nucleation sites. Further, the wetting on the hydrophobic surface with small contact angle increases the critical heat flux (CHF) temperature of the coolant, enabling stable cooling at high heat flux.

This dual-mode functionality provides dynamic adaptation to varying thermal conditions without the need for external controls, ensuring energy efficiency and system reliability. The reversible nature of the hydrogel behavior means that the system can repeatedly transition between hydrophilic and hydrophobic states as heat flux fluctuates, maintaining desirable thermal performance over time. By reducing thermal resistance and enhancing coolant management, this approach is particularly well-suited for applications such as electronics cooling, heat pipes, vapor chambers, and industrial heat exchangers.

Various embodiments of cooling assemblies and systems that include a microfluidic fiber pump are described in detail herein. Whenever possible, the same reference numerals will be used throughout the drawings to refer to the same or like parts.

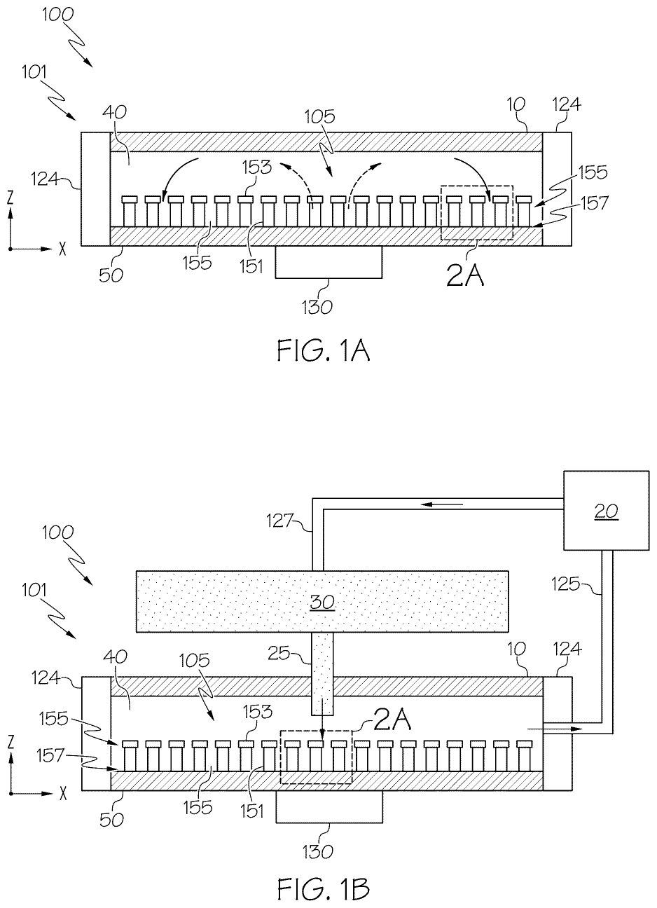

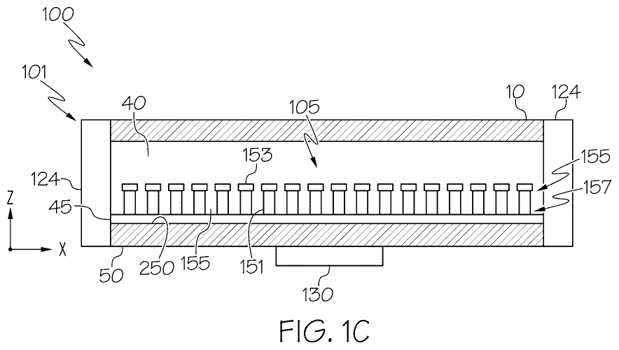

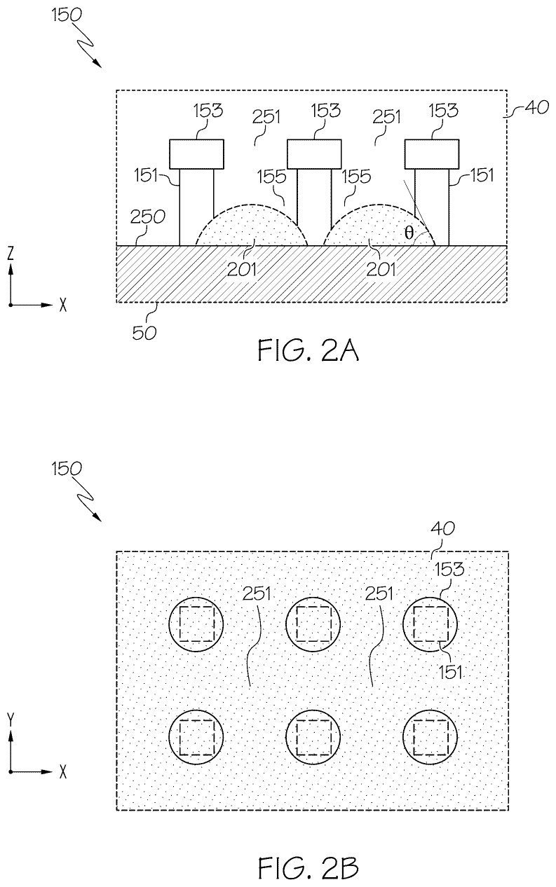

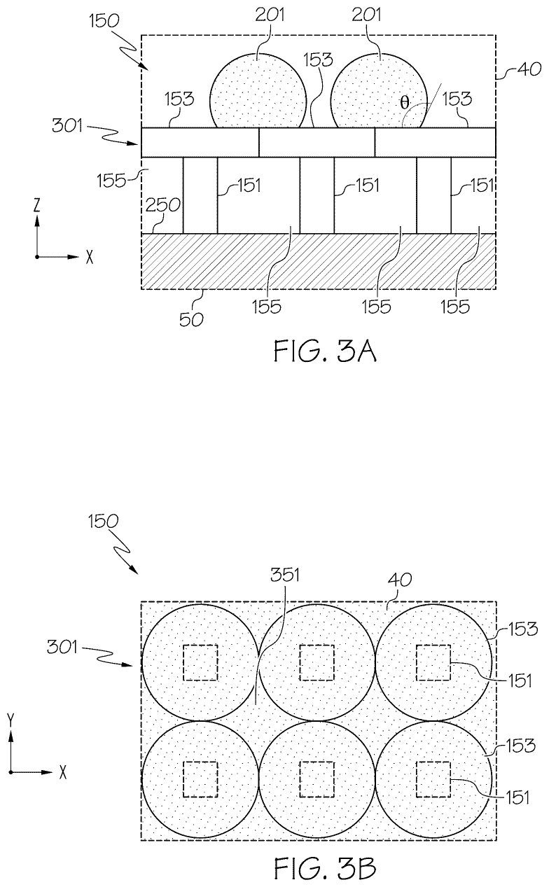

As used herein, the term “device lateral direction” refers to the forward-rearward direction of the device (i.e., in a y-direction of the coordinate axes depicted in FIGS. 2B-3B). The term “device longitudinal direction” refers to the cross-direction of the device (i.e., along the x-axis of the coordinate axes depicted in FIGS. 1A-3B), and is transverse to the lateral direction. The term “device vertical direction” refers to the upward-downward direction of the device (i.e., in the z direction of the coordinate axes depicted in FIGS. 1A-1B, 2A, and 3A). As used herein, “upper” is defined as generally being towards the positive z-axis direction of the coordinate axes shown in the drawings. “lower” or “below” is defined as generally being towards the negative z-axis direction of the coordinate axes shown in the drawings.

As used herein, the term “wick structure” or “wick porous structure” refers to any porous structure that is used to supply condensed liquid within a vapor chamber with capillary action. The wick structure may vary in size, shape, and materials used therein. In one embodiment, the wick structure may have a planar shape with varying thickness. A planar wick structure may include a porous layer. In some embodiments, the wick structure may include a post or pin shape for supplying the condensed liquid. The wick structure may be made from large particles or small particles.

As used herein, the singular forms “a,” “an” and “the” include plural referents unless the context clearly dictates otherwise. Thus, for example, reference to “a” component includes aspects having two or more such components unless the context clearly indicates otherwise.

Turning to the figures, FIGS. 1A-1C schematically depict an example reversible dynamic contact angle cooling system 100 for thermal management of electronic device 130. The assemblies and systems described herein can be applied to different phase-change cooling technologies with similar structures, for example, for phase-change cooling technologies utilizing the energy required for phase transitions (e.g., from liquid to vapor or vice versa) to absorb and dissipate heat from a heat source, such as using liquid-vapor phase transition. Such phase-cooling technologies may include heat pipes, vapor chambers, evaporative cooling, loop heat pipes, thermosyphon cooling, and steam jet ejector cooling systems. In some examples, the heat pipe system and the vapor chamber system may utilize a liquid coolant, such as water, to absorb heat at the hot end, evaporate into vapor, and travel to the cooler end of the pipe or the chamber. At the cool end, the vapor condenses, releasing its heat, and the liquid returns to the hot end via capillary action. The reversible dynamic contact angle cooling system 100 may be a two-phase cooling system. The reversible dynamic contact angle cooling system 100 may include a housing 101. The housing 101 may be configured to be thermally coupled to one or more heat sources subject to thermal regulation, such as an electronic device 130. The housing 101 may include a bottom planar mechanism 50, a side wall 124, an upper wall 10 positioned opposite of the bottom planar mechanism 50, and spaced apart by the side wall 124 to define a cavity 40. The bottom planar mechanism 50 may be which may serve as an evaporator and configured to be thermally coupled to a heat source, such as the electronic device 130, to perform heat exchange between the coolant and the heat source. The reversible dynamic contact angle cooling system 100 may include a pillar array 105 within the cavity 40, which includes a plurality of pillars 151, such as micropillars. The pillar array 105 may include a top end 159 and a bottom end 157. The bottom end 157 of the pillars 151 may be mechanically coupled to the bottom planar mechanism 50. One or more thermosensitive hydrogels 153 may coated on top of the top end 159 of the pillars. In some embodiments, for example, as illustrated in FIG. 1C, the reversible dynamic contact angle cooling system 100 may include a wick 45 attached to the bottom planar mechanism 50. In such embodiments, the bottom end 157 of the pillars 151 may be mechanically coupled to a top surface of the wick 45.

In some embodiments, the housing 101 may include various structures and components, such as, without limitation, a manifold pool, the bottom planar mechanism 50, the side wall 124, the upper wall 10 positioned opposite of the bottom planar mechanism 50, and spaced apart by the side wall 124 to define the cavity 40. In some embodiments, the side walls 124 and the upper wall 10 may be formed as a single continuous wall. For example, the side wall 124 and the upper wall 10 may be formed using additive manufacturing techniques or processes.

As used herein, the terms “additively manufactured” or “additive manufacturing techniques or processes” refer generally to manufacturing processes wherein successive layers of material(s) are provided on each other to “build-up,” layer-by-layer, a three-dimensional component. The successive layers generally fuse together to form a monolithic component which may have a variety of integral sub-components. Although additive manufacturing technology is described herein as enabling the fabrication of complex objects by building objects point-by-point, layer-by-layer, typically in a vertical direction, other methods of fabrication are possible and within the scope of the present subject matter. For example, although the discussion herein refers to the addition of material to form successive layers, one skilled in the art will appreciate that the methods and structures disclosed herein may be practiced with any additive manufacturing technique or manufacturing technology. For example, some embodiments may use layer-additive processes, layer-subtractive processes, or hybrid processes.

Suitable additive manufacturing techniques in accordance with the present disclosure may include, for example, Fused Deposition Modeling (FDM), Selective Laser Sintering (SLS), 3D printing such as by inkjets and laserjets, Sterolithography (SLA), Direct Selective Laser Sintering (DSLS), Electron Beam Sintering (EBS), Electron Beam Melting (EBM), Laser Engineered Net Shaping (LENS), Laser Net Shape Manufacturing (LNSM), Direct Metal Deposition (DMD), Digital Light Processing (DLP), Direct Selective Laser Melting (DSLM), Selective Laser Melting (SLM), Direct Metal Laser Melting (DMLM), and other known processes.

The additive manufacturing processes described herein may be used for forming components using any suitable material. For example, the material may be plastic, metal, concrete, ceramic, polymer, epoxy, photopolymer resin, or any other suitable material that may be in solid, liquid, powder, sheet material, wire, or any other suitable form. More specifically, according to exemplary embodiments of the present subject matter, the additively manufactured components described herein may be formed in part, in whole, or in some combination of materials including but not limited to pure metals, nickel alloys, chrome alloys, titanium, titanium alloys, magnesium, magnesium alloys, aluminum, aluminum alloys, and nickel or cobalt base superalloys (e.g., those available under the name Inconel® available from Special Metals Corporation). These materials are examples of materials suitable for use in the additive manufacturing processes described herein, and may be generally referred to as “additive materials.”

In some embodiments, the side wall 124 and the upper wall 10 may be individually formed through additive manufacturing processes or other manufacturing processes, and coupled to one another via fasteners. Example fasteners include, without limitation, bolt and nut, screw, rivet, adhesive, epoxy, weld, sintering, and/or the like. In some embodiments, one or more of the bottom planar mechanism 50 may include an inner surface and an opposite outer surface. The inner surface may face toward an interior surface of the upper wall 10 to define a portion of the cavity 40. The electronic device 130 may be coupled to the outer surface of the bottom planar mechanism 50. In some embodiments, the electronic device 130 may be bonded to portions of the outer surface of the bottom planar mechanism 50 via a thermal interface layer, which may include a thermally conductive bond and may include a DBC (direct bonded copper) substrate, solder, or some other high-temperature substrate, bonding material, or method. In some embodiments, the thermal interface layer may be a thermal grease positioned between the outer surface of the bottom planar mechanism 50 and the electronic device 130.

In some embodiments, the cavity 40 may include the pillar array 105 arranged above the bottom planar mechanism 50. The bottom end 157 of the pillars 151 may be mechanically attached to the inner surface 250 (e.g., in FIG. 2A) of the bottom planar mechanism 50. The top end 159 of the pillars 151 may have a space distance to the upper wall 10 and may not contact the upper wall 10. As illustrated in FIGS. 1A-1C, in a horizontal or lateral direction, extending in parallel to the bottom planar mechanism 50 and the upper wall 10, the pillars 151 may be spaced apart from each other. The pillars 151 may be arranged side by side in the lateral direction. The pillars 151 may be arranged to define inter-pillar spacing 155 between the pillars 151. The inter-pillar spacing 155 may serve as channels to allow liquid coolant to be supplied to the bottom planar mechanism 50 (e.g., the condensate flow in FIG. 1A). In some embodiments, the pillars 151 may be solid. The inter-pillar spacing 155 can also provide spaces for vapors to be supplied from the bottom planar mechanism 50 (e.g., the evaporation flow as in FIG. 1A). In some embodiments, the pillars 151 may be porous structures in a tube shape with openings at two opposite ends, which may allow liquid coolant to flow to the bottom planar mechanism 50. In some embodiments, the pillars 151 may have micropillared structures.

The pillars 151 may be made of, without limitation, metals (e.g., copper, titanium), polymers (e.g., polydimethylsiloxane), silicon and silicon-based materials, ceramics, or composite materials. The pillars 151 may be formed, without limitation, using lithography technologies. The dimension and shape of the pillars 151 and the inter-pillar spacing 155 may be tailored according to various heat flux requirements. For example, the pillars 151 may be, without limitation, conical pillars, cylindrical pillars, pyramidal pillars, spherical particles, rectangular pillars, and/or free-form shape pillars. The inter-pillar spacing 155 may be any shapes complementary to the surrounding pillars 151. In some embodiments, the pillars 151 may have a dimension (a diameter, a length, or a width) of a base end that is closer to the inner surface 250 of the bottom planar mechanism 50 from 10 nm×10 nm to 10 cm×10 cm, such as from 10 nm×10 nm to 10 cm×10 cm, from 100 nm×100 nm to 1 cm×1 cm, from 1000 nm×1000 nm to 1 mm×1 mm, from 0.01 mm×0.01 mm to 0.1 mm×0.1 mm, or any values between 10 nm×10 nm and 10 cm×10 cm. For example, the base end of the pillars 151 may have a circular shape with a diameter from 10 nm to 100 mm, such as from 10 nm to 10 mm, from 100 nm to 1 mm, from 1000 nm to 0.1 mm, from 0.01 mm to 0.05 mm, or any value between 10 nm to 10 mm. For example, the inter-pillar spacing 155 may be, without limitation, from 1000 nm×1000 nm to 10 cm×10 cm, such as from 0.002 mm×0.002 mm to 8 cm×8 cm, from 0.01 mm×0.01 mm to 5 cm×5 cm, from 0.1 mm×0.1 mm to 1 cm×1 cm, from 1 mm×1 mm to 0.1 cm×0.1 cm, from 10 mm×10 mm to 50 mm×50 mm or any values between 1000 nm×1000 nm and 10 cm×10 cm.

In some embodiments, the top end 159 of the pillars 151 may include one or more thermosensitive hydrogels 153. As described herein, the thermosensitive hydrogels 153 may be hydrogels that respond to changes in temperature by undergoing a reversible sol-gel phase transition or by altering the swelling behavior of the hydrogels. The thermosensitive hydrogels 153 may have a volume transition temperature at which the hydrogels transition between phases or states. For example, in some embodiments, the thermosensitive hydrogels 153 may have a Lower Critical Solution Temperature (LCST). The thermosensitive hydrogel 153 may be in a gel state when the temperature is above the LCST and in a sol state when the temperature is equal to or below the LCST. Accordingly, the thermosensitive hydrogel 153 may swell equal to or below the LCST, and shrink or deswell above the LCST. The LCST of the thermosensitive hydrogels 153 may be from 30° C. to 80° C., from 35° C. to 75° C., from 40° C. to 70° C., from 45° C. to 65° C., from 50° C. to 60° C., or any temperature between 30° C. and 80° C. In some embodiments, the thermosensitive hydrogels 153 may have an Upper Critical Solution Temperature (UCST). The thermosensitive hydrogel 153 may be in a gel state when the temperature is equal to or below the UCST and in a sol state when the temperature is above the UCST. Accordingly, the thermosensitive hydrogel 153 may swell above the UCST, and shrink or deswell equal to or below the UCST. The UCST of the thermosensitive hydrogels 153 may be from 30° C. to 80° C., from 35° C. to 75° C., from 40° C. to 70° C., from 45° C. to 65° C., from 50° C. to 60° C., or any temperature between 30° C. and 80° C.

The thermosensitive hydrogels 153 may include, without limitation, poly(N-isopropyl acrylamide) (PNIPAAm), pluronic/poloxamers (PEO-PPO-PEO), poly(ethylene glycol) (PEG) and its copolymers, poly(vinyl caprolactam) (PVCL), chitosan with β-glycerophosphate, poly(2-oxazoline)-based polymers, polyurethane-based polymers, poly(organophosphazene)-based polymers, methylcellulose, agarose, gelatin, xyloglucan, poly(vinyl alcohol) (PVA)-based copolymers, poly(L-lactic acid-co-glycolic acid)-based hydrogels, and/or any like hydrogel that has the volume transition temperature for a reversible volume change according to the volume transition temperature. The thermosensitive hydrogel 153 may be hydrophobic below the volume transition temperature.

Still referring to FIGS. 1A-1C, the electronic device 130 is depicted, without limitation, as a single electronic device 130. This is non-limiting and there may be two or more electronic devices 130. Further, example electronic device 130 may include, without limitation, a heater, a substrate, cold plates, and other semiconductor devices, that generate a heat load requiring fluid cooling. The electronic device 130 may be a power device that may include one or more semiconductor devices such as, but not limited to, an insulated gate bipolar transistor (IGBT), a reverse conducting IGBT (RC-IGBT), a metal-oxide-semiconductor field-effect transistor (MOSFET), a power MOSFET, a diode, a transistor, and/or combinations thereof. In some embodiments, the electronic device 130 may include a wide-bandgap semiconductor and may be formed from any suitable material such as, but not limited to, silicon carbide (SiC), silicon dioxide (SiO2), aluminum nitride (AlN), gallium nitride (GaN), and boron nitride (BN), and the like. In some embodiments, the electronic device 130 may include ultra-wide-bandgap devices formed from suitable materials such as AlGaN/AlN, Ga₂O₃, and diamond. In some embodiments, the electronic device 130 may operate within a power module having a high current and/or a high power and under high temperatures (for example, in excess of 100° C., 150° C., 175° C., 200° C., 225° C., or 250° C.) and dissipate a large amount of power in the form of heat that must be removed for the continued operation of the electronic device 130. As illustrated in FIGS. 1A-1C, each electronic device 130 may be associated with a liquid input conduit 25 and/or a bottom planar mechanism 50, such that the temperature of each electronic device 130 may be individually tuned through controlling a flow rate of the associated liquid input conduit 25.

In some embodiments, the coolant may include any cooling fluids suitable for heat exchange, evaporation, and/or condensation applications described herein. The coolant may include, without limitation, water, methoxy-nonafluorobutane, perfluoropolyether, fluorinated liquids (e.g., perfluorinated alkanes, perfluorinated ethers), silicone-based oil, R-245fa, and HFE-7100. Other dielectric or refrigerant cooling fluids may be utilized. The liquid coolant may have a viscosity range from about 1 cPa to about 100 cPa, from about 10 cPa to about 90 cPa, from about 20 cPa to about 80 cPa, from about 30 cPa to about 70 cPa, from about 40 cPa to about 60 cPa, or any values between about 1 cPa and about 100 cPa.

The reversible dynamic contact angle cooling system 100 may operate as a closed-cycle cooling system, where the coolant undergoes phase changes and heat exchange entirely within a single chamber, such as the housing 101. For example, FIG. 1A illustrates a cross-sectional view of the reversible dynamic contact angle cooling system 100 as an example closed-cycle cooling system. The upper wall 10 may serve as a condenser. The bottom planar mechanism 50 may serve as an evaporator. As an example vapor flow path in FIG. 1A, the vapor flow path may start at the central area where the bottom planar mechanism 50 absorbs heat generated by the electronic device 130 and causes the coolant to evaporate into vapor. The vapor may follow the evaporation flow from the lower side of the housing 101 to the upper side of the housing 101 to exchange heat with upper wall 10. The cooled vapor may further follow the condensate flow to be condensed into liquid coolant to the edge side near the side wall 124. As a result, condensed liquid may transfer back to the bottom planar mechanism 50.

Alternatively, the reversible dynamic contact angle cooling system 100 may function as an open-cycle cooling system, where the cooled coolant is introduced into a chamber (e.g., the housing 101) to absorb heat, and the heated coolant is transported outside the chamber for cooling before being reintroduced. For example, FIG. 1B illustrates a cross-sectional view of the reversible dynamic contact angle cooling system 100 as an example open-cycle cooling system. The reversible dynamic contact angle cooling system 100 may include an external condenser 20, a fluid reservoir 30, and the housing 101 to form a fluid flow loop. The housing 101 may include the bottom planar mechanism 50, the side wall 124, the upper wall 10 positioned opposite of the bottom planar mechanism 50, and spaced apart by the side wall 124 to define the cavity 40. The bottom planar mechanism 50 may be configured to perform heat exchange between coolant and one or more heat sources, such as electronic device 130. In some embodiments, the fluid reservoir 30 may be fluidly coupled to the external condenser 20 via a first conduit 127 in an inflow direction, and fluidly coupled to the housing 101 via a plurality of liquid input conduit 25 in an outflow direction. The housing 101 may be fluidly coupled to the external condenser 20 via a second conduit 125. In some embodiments, the cavity 40 may be fluidly coupled to the external condenser 20. The housing 101 may be positioned downstream of the fluid reservoir 30 via the liquid input conduit 25. The reversible dynamic contact angle cooling system 100 may include a pump, such as a micropump, to control a flow direction in the liquid input conduit 25, the second conduit 125, and/or the first conduit 127 and a flow rate of liquid coolant that flows within, as depicted by the arrow labeled in FIG. 1B, from the fluid reservoir 30, through the liquid input conduit 25, into the cavity 40 of the housing 101, from the cavity 40, through the second conduit 125, to the external condenser 20, and from the external condenser 20, through the first conduit 127, to the fluid reservoir 30.

In some embodiments, as illustrated in FIG. 1C, the housing 101 may include a wick 45 connected to the inner surface 250 (e.g., in FIG. 2A) of the bottom planar mechanism 50. The wick 45 may include a porous structure that includes an upper surface, an opposite lower surface, a pair of side walls, and a pair of end walls that define a thickness. The wick 45 may be porous such that the liquid coolant, such as liquid coolant and/or other fluids, may enter, pass through and, in some embodiments, make contact with, or be fluidly coupled to the inner surface 250 of the bottom planar mechanism 50. The lower surface of the wick 45 may be positioned at or extend from the inner surface 250 (e.g., in FIG. 2A) of the bottom planar mechanism 50 in the vertical direction (i.e., in the z-direction). The wick 45 may be dimensionally sized to match, or be equal to the size of the electronic device 130 coupled to the outer surface of the bottom planar mechanism 50. The wick 45 may be, without limitation, in a rectangular shape, a square shape, a hexagonal shape, an octagonal shape, a circular shape, a triangular shape, and/or the like. As such, the wick 45 may be any shape, size, and/or dimension. Further, in non-limiting examples, the wick 45 may be formed by a sintered copper (Cu) particle wick, a copper inverse opal wick, a wick formed by sintering stacked meshes, a wick that is laser patterned in Cu or a ceramic, a Cu wick that includes simple capillary grooves in a base material, and the like.

In some embodiments, the wick 45 may be a monolithic single structure formed with the bottom planar mechanism 50 to extend from and be fluidly coupled to an inner surface 250 of the bottom planar mechanism 50 at or near the positioning of the electronic device 130. The wick 45 may be positioned to extend from the inner surface in the vertical direction (i.e., in the z-direction). In some embodiments, the wick 45 may be separate from the bottom planar mechanism 50 and is fluidly coupled to the inner surface 250 (e.g., in FIG. 2A) of the bottom planar mechanism 50. For example, in this embodiment, the wick 45 may be coupled to the inner surface 250 of the bottom planar mechanism 50 via a thermally conductive bond and may include a DBC (direct bonded copper) substrate, solder, or some other high-temperature substrate, bonding material, or method.

Further, in some embodiments, the wick 45 may extend in the longitudinal direction (i.e., in the x direction) a length less than portions of the housing 101 that abut with the interior surface of the upper wall 10 to provide one or more vapor outlets such that when the fluid makes contact with, or in close proximately to the bottom planar mechanism 50, which absorbs heat generated at the electronic device 130, the vapor created or generated as part of the cooling process, may be expelled, and further transmitted to the second conduit 125. That is, in operation, the wick 45 can draw the liquid via capillary force where the liquid coolant evaporates to vapor due to the heat from the electronic device 130. In addition, it should be understood that for a given manifold design or configuration, there is a certain amount of flooding that takes place, which results in different operating points where the fluid begins to evaporate.

Referring to FIGS. 2A-3B, embodiments of dynamically adaptive surface wetting conditions of the reversible dynamic contact angle cooling system 100 are depicted. The reversible dynamic contact angle cooling system 100 may cause the liquid nuclei 201 to nucleate on different surfaces, such as on the inner surface 250 of the bottom planar mechanism 50 as in FIGS. 2A and 2B, or on the surface of the thermosensitive hydrogels 153 as in FIGS. 3A and 3B, and have different contact angle θ according to the heat flux.

For example, FIGS. 2A and 2B illustrate a partially isolated view of the example reversible dynamic contact angle cooling system 100 of FIGS. 1A and 1B at high heat flux. As illustrated in FIGS. 2A and 2B, when the heat source, such as the electronic device 130 is at a relatively high temperature (e.g., above 40, 50, 60, 70, 80, 90, or 100° C.), the heat absorbed by the bottom planar mechanism 50 may cause the temperature of the thermosensitive hydrogels 153 to be above the volume transition temperature. The volume transition temperature may be the LCST or the UCST of the thermosensitive hydrogels 153, as described further above. The thermosensitive hydrogels 153 may be in a shrunk shape above the volume transition temperature to define one or more openings 251 at the top end 159 of the pillars 151 to facilitate passages of coolant at high heat flux. Accordingly, the liquid coolant may be continuously filled in the inter-pillar spacing 155 such that the inter-pillar spacing 155 may be configured to be filled with liquid coolant.

In some embodiments, the size of the thermosensitive hydrogels 153 may be comparable to a diameter or a width of the pillars 151 at temperature above the volume transition temperaure. The size of the thermosensitive hydrogels 153 may be less than the spacing between any pair of pillars 151, such as, without limitation, 0.01, 0.1, 0.2, 0.3, 0.4, 0.5, 0.6, 0.7, 0.8, 0.9 of a spacing distance between a pair of neighbor pillars 151, or any value between 0.01 and 0.9 of the spacing distance between the pair of neighbor pillars 151.

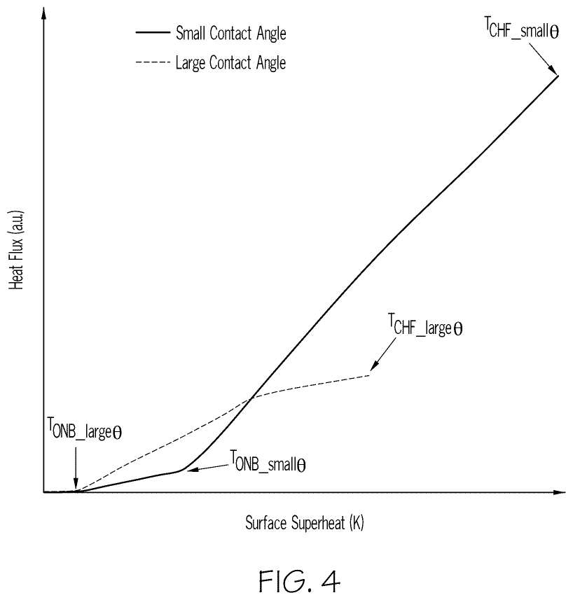

In some embodiments, the inner surface 250 of the bottom planar mechanism 50 may be hydrophilic. In a wetting process of the coolant to form the liquid nuclei 201, the hydrophilic inner surface 250 may cause a small contact angle θ (e.g., below 90 degrees) of the liquid nuclei 201, which would promote the spreading of the liquid nuclei 201 for faster heat removal, and therefore increasing the wettability of the boiling surface. Further, as illustrated in FIG. 4, a small contact angle θ of the liquid nuclei 201 can allow the coolant to have a greater onset of nucleate boiling temperature (T_{ONB}) at low heat flux and a greater critical heat flux temperature (T_{CHF}) at high heat flux, compared with the coolant having a large contact angle θ. The greater T_{CHF} allows the disclosed assemblies and systems to handle higher heat flux before transitioning from the nucleate boiling regime to the less efficient film boiling regime. The nucleate boiling regime may ensure vigorous bubble formation and detachment, enhancing heat transfer efficiency. A higher T_{CHF} allows the system to remain in this regime at greater heat flux, preventing premature transition to film boiling, which can lead to significantly reduced cooling performance. Accordingly, by allowing the coolant to pass the openings 251 and to nucleate on the hydrophilic inner surface 250 of the bottom planar mechanism 50, the reversible dynamic contact angle cooling system 100 can sustain desired heat transfer at higher temperatures and heat loads.

For example, FIGS. 3A and 3B illustrate a partially isolated view of the example reversible dynamic contact angle cooling system 100 at low heat flux. When the heat source, such as the electronic device 130 is at low temperature, the heat absorbed by the bottom planar mechanism 50 may cause the temperature of the thermosensitive hydrogels 153 to be equal to or below the volume transition temperature. The volume transition temperature may be the LCST or UCST of the thermosensitive hydrogels 153, as described further above. The thermosensitive hydrogels 153 may be in a swelled shape below the volume transition temperature to form a blocking layer 301 with limited pores 351 and/or absence of the openings 251 (e. g, as in FIGS. 2A-2B) at the top end 159 of the pillars 151, which blocks the majority or all of the coolant from passing the blocking layer 301 to the inter-pillar spacing 155 and/or the inner surface 250 of the bottom planar mechanism 50. Accordingly, the inter-pillar spacing 155 may be configured to be filled with liquid coolant and air when the temperature of the thermosensitive hydrogels 153 is equal to or below the volume transition temperature. In some embodiments, the size of the thermosensitive hydrogels 153 at a temperature equal to or below may have a diameter comparable to the spacing between any pair of pillars 151, such as, without limitation, 0.7, 0.8, 0.9, 1.0 of a spacing distance between a pair of neighbor pillars 151, or any value between 0.7 and 1.0 of the spacing distance between the pair of neighbor pillars 151.

In some embodiments, the thermosensitive hydrogels 153 may be hydrophobic. The coolant may nucleate on the top surface of the thermosensitive hydrogels 153. In a wetting process of the coolant to form the liquid nuclei 201, the hydrophobic surface of the thermosensitive hydrogels 153 may cause a large contact angle θ (e.g., equal to or greater than 90 degrees) of the liquid nuclei 201 at a low heat flux. The wettability of the boiling surface may be reduced to balance the cooling rate. Hydrophobic surfaces repel coolant, causing the liquid nuclei 201 to spread less and form contact angles ranging from 90° to 180°, resulting in larger droplet diameters. This hydrophobic surface of the hydrogels allows the coolant to nucleate with a large wetting angle to support dropwise boiling and reduces the thermal resistance associated with liquid films. Moreover, the large contact angle lowers the onset of the nucleate boiling point of the coolant, allowing for improved thermal management under these conditions.

Further, as illustrated in FIG. 4, a larger contact angle θ of the liquid nuclei 201 can allow the coolant to have a smaller onset of nucleate boiling temperature (T_{ONB}) at high heat flux and a smaller critical heat flux temperature (T_{CHF}) at low heat flux, compared with the coolant having a small contact angle θ. The lower T_{ONB} may cause an early evaporation of the coolant and prevent surface temperatures from undesirably rising under low heat flux and thus allow the disclosed assemblies and systems to reduce pumping requirements (less coolant is required for cooling at the low heat flux), achieve efficient heat dissipation, and maintain operating temperatures more efficiently at low temperature.

Referring to FIG. 4, a non-limiting coolant boiling curve in the reversible dynamic contact angle cooling system 100 is depicted. The non-limiting plotted curves represent the coolant boiling properties, such as, the surface superheat, against the heat flux. For example, the plots include a small contact angle boiling curve in a solid line and a large contact angle boiling curve in a dashed line. As the surface temperature of the liquid nuclei (such as the liquid nuclei 201 in FIGS. 2A and 3A) is increased, bubbles may appear on the nucleation surface (e.g., the blocking layer 301 of the thermosensitive hydrogels 153 in FIG. 3A and the inner surface 250 of the bottom planar mechanism 50 in FIG. 2A). When the temperature of the liquid nuclei 201 is below T_{ONB}, the boiling curve is the natural convection regime, in which the heat transfer is by single-phase flow without vapor generation. When the temperature of the liquid nuclei 201 rises above T_{ONB} but below T_{CHF}, the boiling curve is the nucleate boiling, which is characterized by a very high rate of heat extraction at the surface of the part. As illustrated in FIG. 4, the coolant may have a lower T_{ONB} for a small contact angle (e.g., when the coolant may nucleate on the inner surface 250 of the bottom planar mechanism at low heat flux) compared with the T_{ONB} for large contact angle (e.g., when the coolant may nucleate on the surface of thermosensitive hydrogels 153 at high heat flux), and have a higher a T_{CHF} for small contact angle surface compared with the T_{CHF} for a large contact angle.

Accordingly, the embodiments described herein are directed to reversible dynamic contact angle cooling assemblies and systems that include a housing with a cavity to host an array of pillars having a top side including hydrogels and a bottom side connected to a bottom planar mechanism. The assemblies and systems can switch between a high heat flux mode and a low heat flux mode. In the high heat flux mode, the hydrogels can shrink to allow coolant to pass the hydrogels and the pillars to have heat exchange with the bottom planar mechanism. In the low heat flux mode, the hydrogels can swell to form a blocking layer to reduce or stop the coolant from having heat exchange with the bottom planar mechanism. Instead, the coolant may nucleate on the surface of the hydrogels. The dual operation mode of the assemblies and systems are reversible and automatic, according to the working conditions to enhance the thermally control efficiency over a heat source, such as an electronic device.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

1. A cooling assembly for phase-change cooling and thermal management, comprising:
a housing comprising a bottom planar mechanism, a side wall, an upper wall positioned opposite of the bottom planar mechanism and spaced apart by the side wall to define a cavity;
one or more pillars arranged within the cavity, the pillars comprising a top end and a bottom end; and
wherein:
the top end of the pillars comprises one or more thermosensitive hydrogels, and
the bottom end of the pillars is mechanically coupled to the bottom planar mechanism.

2. The cooling assembly of claim 1, wherein the thermosensitive hydrogels is configured to swell to form a blocking layer above the top end of the pillars at low heat flux.

3. The cooling assembly of claim 2, wherein the blocking layer is configured to receive coolant.

4. The cooling assembly of claim 1, wherein the thermosensitive hydrogels are configured to shrink to define one or more openings at the top end of the pillars to facilitate passages of coolant at high heat flux.

5. The cooling assembly of claim 4, wherein the bottom planar mechanism is configured to receive the coolant passed the openings.

6. The cooling assembly of claim 1, wherein the bottom planar mechanism comprises a hydrophilic surface.

7. The cooling assembly of claim 1, wherein the thermosensitive hydrogels are hydrophobic at low heat flex.

8. The cooling assembly of claim 1, wherein the thermosensitive hydrogel have a volume transition temperature.

9. The cooling assembly of claim 8, wherein the thermosensitive hydrogels are configured to swell equal to or below the volume transition temperature.

10. The cooling assembly of claim 8, wherein the one or more pillars define an inter-pillar spacing, the inter-pillar spacing is configured to be filled with liquid and gas equal to or below the volume transition temperature.

11. The cooling assembly of claim 8, wherein the thermosensitive hydrogels are configured to shrink above the volume transition temperature.

12. The cooling assembly of claim 8, wherein the one or more pillars define an inter-pillar spacing, the inter-pillar spacing is configured to be filled with liquid above the volume transition temperature.

13. A cooling assembly for phase-change cooling and thermal management, comprising:
a housing comprising a bottom planar mechanism, a side wall, an upper wall positioned opposite of the bottom planar mechanism and spaced apart by the side wall to define a cavity;
one or more pillars arranged within the cavity, the pillars comprising a top end and a bottom end;
a condenser fluidly coupled to the cavity; and
wherein:
the top end of the pillars comprises one or more thermosensitive hydrogels, and
the bottom end of the pillars is mechanically coupled to the bottom planar mechanism.

14. The cooling assembly of claim 13, wherein:
the thermosensitive hydrogels are configured to swell to form a blocking layer above the top end of the pillars at low heat flux; and
the blocking layer is configured to receive coolant.

15. The cooling assembly of claim 13, wherein:
the thermosensitive hydrogels are configured to shrink to define one or more openings at the top end of the pillars to facilitate passages of coolant at high heat flux; and
the bottom planar mechanism is configured to receive the coolant passed the openings.

16. The cooling assembly of claim 13, wherein the bottom planar mechanism comprises a hydrophilic surface.

17. The cooling assembly of claim 13, wherein the thermosensitive hydrogels are hydrophobic at low heat flex.

18. The cooling assembly of claim 13, wherein the thermosensitive hydrogels have a volume transition temperature.

19. The cooling assembly of claim 18, wherein:
the thermosensitive hydrogels are configured to swell equal to or below the volume transition temperature; and
the one or more pillars define an inter-pillar spacing, the inter-pillar spacing is configured to be filled with liquid and gas equal to or below the volume transition temperature.

20. The cooling assembly of claim 18, wherein:
the thermosensitive hydrogels are configured to shrink above the volume transition temperature; and
the one or more pillars define an inter-pillar spacing, the inter-pillar spacing is configured to be filled with liquid above the volume transition temperature.
